(19) United States
(12) Patent Application Publication
(10) Pub. No.: US 2012/0000789 A1
(43) Pub. Date: Jan. 5, 2012

(54) STRUCTURED GAS DIFFUSION ELECTRODE FOR ELECTROLYSIS CELLS

(75) Inventors: Thomas Turek, Goslar (DE); Imad Moussallem, Clausthal-Zellerfeld (DE)

(73) Assignee: Bayer Technology Services GMBH, Leverkusen (DE)

(21) Appl. No.: 13/142,905

(22) PCT Filed: Dec. 29, 2009
(86) PCT No.: PCT/EP09/09295

§ 371 Date: Sep. 20, 2011

(30) Foreign Application Priority Data
Jan. 8, 2009 (DE) 102009004031.5

(51) Int. Cl. C25B 9/08; C25B 1/46; H05K 13/00; C25B 1/26

(52) U.S. Cl. 205/516; 204/252; 205/620; 29/592.1

(57) ABSTRACT

Electrolysis cell for membrane-supported electrolysis, comprising an oxygen-consuming cathode.

The invention relates to a novel gas diffusion electrode for the reduction of oxygen which is preferably used in chloralkali electrolysis.

The reduction of oxygen by means of electrochemical processes and apparatuses is an essential process in, for example, the preparation of chlorine. The reduction of oxygen is carried out, in particular, using gas diffusion electrodes which are generally also known as oxygen-consuming cathodes.

In generally known electrolysis cells, chloride (from sodium chloride solutions) is oxidized to chlorine on the anode side according to formula (I), usually with application of an electric potential, while water is reduced to hydrogen according to formula (II) on the cathode side.

2·Cl⁻→Cl₂+2·e⁻E⁰=+1.36 V (I)

2·H₂O+2·e⁻→2·OH⁻+H₂ E⁰=−0.83 V (II)

The minimum thermodynamic decomposition potential for the oxidation and reduction according to the combination of formulae (I) and (II) which is to be applied over the electrolysis cell is thus 2.19 V.

If the actually undesirable hydrogen formation according to formula (II) is able to be suppressed by the use of an oxygen-consuming cathode on the cathode side and a reaction according to formula (III) in which oxygen is electrochemically reduced to hydroxide ions

O₂+2·H₂O+4e⁻→4·OH⁻; E⁰=+0.4 V (III)

is able to be carried out, the thermodynamic decomposition potential for the oxidation and reduction according to the combination of formulae (I) and (III) which is to be applied over the electrolysis cell can be reduced to 0.96 V. It is in this way theoretically possible to reduce the decomposition potential required by 1.23 V.

Since, as just described, the abovementioned potentials and reactions according to the formulae (I) to (III) are thermodynamically ideal limiting cases and the abovementioned thermodynamic decomposition potential to be applied over the electrolysis cell is therefore also a thermodynamically ideal limiting case which disregards physicochemical effects such as overvoltages on electrode surfaces, the abovementioned saved voltage of 1.23 V can never be achieved in real processes.

In industrial processes, any savings in such necessary potentials lead to considerable potential savings in respect of the electric energy which has to be supplied to the process since the price of this energy has risen steadily, especially in recent years.

The abovementioned overvoltages are to a certain extent caused by the construction of the electrodes used, which cause, for instance, unnecessary ohmic resistances.

Thus, U.S. Pat. No. 5,733,430 discloses a gas diffusion electrode for use in sodium chloride electrolysis, in which oxygen may be present in an alkaline solution and is reduced by means of the electrode disclosed. The gas diffusion electrode disclosed comprises a gas- and liquid-permeable layer of metal onto whose surface a catalyst material is applied and also a gas- and liquid-permeable metal collector which is joined to the gas- and liquid-permeable metal layer. The catalyst material is a mixture of silver and/or gold particles and particles containing a fluorine compound in order to increase the hydrophobicity of the surface. The abovementioned gas- and liquid-permeability is achieved, according to U.S. Pat. No. 5,733,430, by the metal layer and the metal collector being configured as porous material, e.g. as mesh or grid, or as sintered structure. Hole diameters of from 1 to 55 mm are disclosed for the metal collector. The metal collector and metal layer are usually in area contact with one another and comprise silver and/or gold on at least their respective surface.

U.S. Pat. No. 5,733,430 does not disclose structuring of the surface of the electrodes obtained. The examples make it obvious, because of the pressing together of metal layer and metal collector according to the disclosure, that a level, flat configuration is present.

Such an electrode is disadvantageous because although a possibly reduced chemical attack area on the electrode material can be assumed due to its flat configuration, a necessarily large-area electrode, which is structurally disadvantageous, results at the same time. Any reduction of oxygen is therefore only possible when using a plurality of large-area electrodes according to the disclosure of U.S. Pat. No. 5,733,430 or alternatively with a disproportionately increased current.

US 2007/0095676 A1 discloses a further electrode and electrolysis cell construction in which the reactions according to the formulae (I) and (II) can be carried out with application of an electric potential. The cathode is configured as an oxygen-consuming cathode similar to that in the disclosure of U.S. Pat. No. 5,733,430. The electrolysis cell according to US 2007/0095676 A1 using such oxygen-consuming cathodes can have two structural forms.

Either there is a gap through which water and/or alkali is passed between the cathode and the polymer membrane located between cathode and anode or the cathode is in direct contact with the abovementioned polymer membrane with which the anode is in turn in direct contact. The electrode surfaces of US 2007/0095676 A1 are likewise not disclosed as deliberately structured.

The first embodiment according to US 2007/0095676 A1 is disadvantageous because it results in a further ohmic resistance in the form of the abovementioned gap though which water and/or alkali is passed and this ohmic resistance has to be overcome in order for current for the reduction of oxygen to flow.

The second embodiment according to US 2007/0095676 A1 is disadvantageous because although the abovementioned ohmic resistance is no longer present, on the other hand the oxygen-consuming cathode can no longer operate as efficiently since an electrolyte flow, which could formerly be conveyed behind the oxygen-consuming cathode now opposes the inflow of oxygen molecularly dissolved in the liquid which is to be reduced. Thus, US 2007/0095676 A1 discloses that, in this embodiment, the hydroxide ions formed from the oxygen have to be conveyed in the form of sodium hydroxide away from the electrode surface. In order for a stronger driving force of the oxygen to the cathode surface, which may be able to compensate for this disadvantage, to be present, a higher potential again has to be applied, which in turn is disadvantageous, as described above.

U.S. Pat. No. 6,117,286, which refers to the abovementioned US 2007/0095676 A1 and seeks, in particular, to achieve a technical solution to the disadvantage of the first embodiment having a gap between the oxygen-consuming cathode and polymer membrane, discloses an arrangement which is similar to the second embodiment of US 2007/0095676 A1 but differs therefrom in that a further layer of a hydrophilic, liquid-permeable material is present between the oxygen-consuming cathode and the polymer membrane.

Although the spacing between the anode and the cathode can be reduced in this way and the disadvantages of the second embodiment according to US 2007/0095676 A1 can at the same time be overcome since the hydroxide ions can now be discharged via the layer of a hydrophilic, liquid-permeable material. On the other hand a further material is in this way introduced between the anode and the cathode and this produces a further ohmic resistance. The above-mentioned disadvantages therefore continue to be present according to the disclosure of U.S. Pat. No. 6,117,286, even though possibly to a reduced extent.

U.S. Pat. No. 6,117,286 further discloses that the surface geometry of the cathode and anode sides cannot be planar. Moreover, the alteration of the surface geometry according to U.S. Pat. No. 6,117,286 is made in order to allow better outflow of liquid comprising hydroxide ions from the layer of a hydrophilic, liquid-permeable material. The cathode surface is therefore provided with cut-outs through which the layer of hydrophilic, liquid-permeable material penetrates. This design is disadvantageous since the electrode surface area of the oxygen-consuming cathode has to be sacrificed as a result, which in turn, if the original performance of the unperforated oxygen-consuming cathode is to be regained, results either in the necessity of an increase in the energy employed (in the form of increased potential and/or current) or in the necessity of a larger construction. Both variants are economically disadvantageous.

An advantage of structured surfaces in combination with electrolytic processes is disclosed in U.S. Pat. No. 3,493,487. U.S. Pat. No. 3,493,487 discloses an electrolysis apparatus comprising anodes and cathodes which can be separated from one another by coating of the cathode surface. Structuring of the cathode surface is achieved according to U.S. Pat. No. 3,493,487 by means of metal sheets which have small openings and are in turn stabilized by means of a corrugated structure in their interior to increase. However, the arrangement disclosed does not relate unambiguously to membrane-supported electrolysis processes.

The arrangement disclosed in U.S. Pat. No. 3,493,487 has the disadvantage that either no separation between anode space and cathode space by means of a membrane is provided, so that mixing of anolyte and catholyte cannot be avoided, or when a coating is provided on the cathode, this is completely covered, so that oxygen can only gain access through the coating and the reduction of oxygen can therefore only be carried out very slowly if at all. This results from the fact that the field of application of the arrangement disclosed in U.S. Pat. No. 3,493,487 is clearly not membrane-supported electrolysis as is disclosed, for instance, in U.S. Pat. No. 5,733,430, US 2007/0095676 A1 or U.S. Pat. No. 6,117,286 as field of application of the apparatuses.

In the light of the prior art, it is therefore still an object to provide an electrolysis cell for membrane-supported electrolysis which comprises an oxygen-consuming cathode and no longer has the disadvantages of the prior art.

It has surprisingly been found, as first subject of the present invention, that an apparatus for the electrolytic reduction of oxygen containing a first electrode (1) as anode, a polymer membrane (2) and a second gas- and liquid-permeable electrode (3) as cathode, characterized in that the second electrode (3) is in contact with the polymer membrane (2) at points and/or lines of contact, can achieve this object.

The first electrode (1) is usually in the form of a plate, a flat mesh, a flat grid or a flat woven fabric.

In alternative embodiments of the apparatus of the invention, the first electrode (1) can also be in contact with the polymer membrane (2) at points and/or lines of contact.

If the first electrode (1) is in the form of a plate, it can be porous or nonporous.

The first electrode (1) is preferably in the form of a porous plate, a flat mesh, a flat grid or a flat woven fabric.

The first electrode (1) is particularly preferably in the form of a porous plate.

If the first electrode (1) is porous, it is at the same time also gas- and liquid-permeable.

In the context of the present invention, gas- and liquid-permeable means that the respective electrode does not prevent permeation of gas when high gauge pressures are applied. However, these electrodes usually generate a counterpressure against such permeation as a result of capillary pressures, so that no gas permeation takes place in the process of the invention for chloralkali electrolysis. However, there is at the same time the possibility of diffusion of substances molecularly dissolved in the surrounding liquids.

The preferred and particularly preferred embodiments of the first electrode (1) are advantageous because these have a particularly large specific surface area per component volume as a result of the porous or open-pored structure. The particularly preferred embodiment of the first electrode (1) is still more advantageous because this has not only the abovementioned particularly large specific surface area per component volume but also a high mechanical stability which stabilizes the entire apparatus.

The first electrode (1) usually comprises a material selected from the group consisting of carbon black, graphite, carbon nanotubes, titanium, titanium alloys and special metal alloys.

Preferred materials of which the first electrode (1) is composed are the materials selected from the group consisting of graphite, titanium, titanium alloys and special metal alloys which are generally known to those skilled in the art under the names Hastelloy and Incolloy.

The abovementioned first electrode (1) can also be coated. In preferred embodiment, the first electrode (1) is coated with a material selected from the group consisting of ruthenium oxide (RuO₂) and iridium oxide (IrO₂).

The abovementioned materials are advantageous because they generally have a good electrical conductivity but at the same time also good chemical stability towards the electrolyte solutions comprising sodium chloride and/or hydrogen chloride and/or chlorine on the anode side, which is particularly advantageous for use of the apparatus in connection with chlorine electrolysis.

For the purposes of the present invention, a material is referred to as chemically stable if it undergoes no chemical reaction with the surrounding electrolyte solutions comprising, for example, sodium chloride and/or hydrogen chloride and/or chlorine under the operating conditions of the apparatus.

The polymer membrane (2) is usually a polymer membrane as is generally known under the name cation-exchange membrane to those skilled in the art.

Preferred polymer membranes (2) comprise polymeric perfluorosulphonic acids.

The polymer membrane (2) can also comprise reinforcing fabrics composed of other chemically stable materials, preferably fluorinated polymers and particularly preferably polytetrafluoroethylene.

The preferred polymer membranes (2) are advantageous since they are cation-exchange membranes and thus aid the permeation of ions through the membrane. This in turn leads to a lower ohmic resistance across the membrane, which reduces the potential required for achieving a flow of current.

The thickness of the polymer membrane (2) is usually less than 1 mm. The thickness of the membrane is preferably less than 500 μm, particularly preferably less than 400 μm, very particularly preferably less than 250 μm.

The low thicknesses of the membrane are particularly advantageous because this enables the potential required in the apparatus to be made smaller since the ohmic resistance is reduced.

The second electrode (3) is gas- and liquid-permeable and can for this purpose be in the form of a porous material, a mesh, a grid or a woven fabric.

The second electrode (3) is preferably in the form of a mesh, a grid or a woven fabric.

The second electrode (3) is particularly preferably in the form of a mesh or a grid.

The preferred and particularly preferred configurations as mesh or grid of the second electrode (3) are advantageous because such configurations can easily be made from the materials described below for the second electrode (3) and because these can easily be shaped in such a way that the points and/or lines of contact according to the invention with the polymer membrane (2) can be obtained on contacting.

The second electrode (3) usually comprises a material selected from the group consisting of carbon black, graphite, carbon nanotubes, nickel, silver, titanium, titanium alloys and special metal alloys.

The material of the second electrode (3) is preferably nickel, silver and/or titanium or an alloy thereof.

It is possible for a coating to be present or absent on the second electrode (3). Preference is given to a coating being present on the second electrode (3).

In preferred developments of the apparatus described here, the first electrode (1) can also be coated in the same way as or in a similar way to the second electrode (3).

If a coating is present on the second electrode (3), this is usually a coating comprising a conductive metal or a fluorinated polymer.

Conductive metals which are preferably present in the coating on the second electrode (3) are metals selected from the group consisting of iron, manganese, cobalt, gold, iridium, copper, platinum, palladium, osmium, rhodium, ruthenium and silver.

The oxides of the abovementioned conductive metals and/or alloys thereof and/or mixtures thereof can likewise preferably also be present in the coating of the second electrode (3).

Particular preference is given to silver.

A preferred fluorinated polymer is polytetrafluoroethylene (PTFE).

The preferred coating of the second electrode (3) is advantageous because it is readily possible, by means of the ratios of conductive metal and fluorinated polymer and by appropriate choice of the conductive metal and the fluorinated polymer, for a person skilled in the art to match the second electrode (3) in terms of the hydrophilicity/hydrophobicity and in terms of the chemical stability to the requirements of the process in which the apparatus according to the invention is to be used while at the same time keeping the ohmic resistance produced by the additional coating on the second electrode (3) small.

For example, a person skilled in the art can, when the apparatus is used in connection with chloralkali electrolysis, achieve the desired low ohmic resistances and an essentially hydrophilic surface by a coating with polytetrafluoroethylene in small proportions and a higher proportion of, for example, silver which in such a coating is chemically stable against attack by chloride ions and chlorine, so that the electrochemical reduction of oxygen occurs in an advantageous manner.

When the apparatus is used for chloralkali electrolysis, it is therefore preferred for the coating on the second electrode (3) to comprise a proportion of more than 80% by weight of silver, particularly preferably 90% by weight of silver, very particularly preferably more than 95% by weight of silver.

In this connection, it is likewise preferred for the coating on the second electrode (3) to comprise a proportion of polytetrafluoroethylene of less than 20% by weight, particularly preferably less than 10% by weight, very particularly preferably from 0.2 to 7% by weight.

The second electrode (3) is, according to the invention, in contact with the polymer membrane (2) at points and/or lines of contact.

In a first preferred embodiment of the apparatus of the invention for the electrolytic reduction of oxygen, the second electrode (3) is corrugated or zig-zagged in one direction in space and is in contact with the polymer membrane (2) at lines of contact.

In a second preferred embodiment of the apparatus of the invention for the electrolytic reduction of oxygen, the second electrode (3) is corrugated or zig-zagged in two directions in space and is in contact with the polymer membrane (2) at points of contact.

In a third preferred embodiment of the apparatus of the invention for the electrolytic reduction of oxygen, the second electrode (3) is corrugated or zig-zagged in one direction in space in a first region and in this first region is in contact with the polymer membrane (2) at lines of contact and in a second is corrugated or zig-zagged in two directions in space region and in contact with the polymer membrane (2) at points of contact.

For the purposes of the present invention, corrugated or zig-zagged in one or two directions in space means that the second electrode (3) is deformed in directions in space perpendicular to the surface of the polymer membrane (2) with which it is in contact at points or lines of contact.

Particularly preferred embodiments of such second electrodes (3) which are corrugated and/or zig-zagged in one and/or two directions in space are characterized in that the deformation relative to the points and/or lines of contact with the polymer membrane is at a distance of from 0.1 to 5 mm from the point of each deformation furthest from the polymer membrane.

Distances smaller than those indicated above are, because of tolerances, frequently very difficult to produce and therefore not particularly advantageous from an economic point of view, while distances larger than those indicated above lead to larger average distances between second electrode (3) and polymer membrane (2), which result in excessively high average ohmic resistances and are therefore disadvantageous.

An example of an embodiment which is corrugated in one direction in space is the configuration of the second electrode (3) in the form of a corrugated sheet made of the porous materials, meshes, grids or woven fabrics according to the invention.

An example of an embodiment which is zig-zagged in one direction in space is the configuration of the second electrode (3) in the form of a zig-zagged sheet made of the porous materials, meshes, grids or woven fabrics according to the invention.

An example of an embodiment which is corrugated in two directions in space is the configuration of the second electrode (3) in the form of a sheet made of the porous materials, meshes, grids or woven fabrics according to the invention, with periodic flattened areas.

An example of an embodiment which is zig-zagged in two directions in space is the configuration of the second electrode (3) in the form of a sheet made of the porous materials, meshes, grids or woven fabrics according to the invention which is provided with periodic, pyramidal depressions.

The embodiment according to the invention of the second electrode (3) in which the latter is in contact with the polymer membrane (2) at points and/or lines of contact is particularly advantageous because the direct contact with the polymer membrane (2) makes the ohmic resistance minimal at such places and at the same time a space is formed at the places at which direct contact does not occur, and the hydroxide ions formed can be discharged through this space without them having to be carried away from the second electrode (3) in countercurrent to the oxygen with which the second electrode is to be brought into contact. In this way, both a low ohmic resistance over the direct contact and at the same time a lower ohmic resistance due to the absence of diffusive inhibition of the inward transport of oxygen are achieved. Overall, the electric potential necessary is minimized as a result.

In this context, the configuration of the second electrode (3) according to the first preferred embodiment as corrugated or zig-zagged in one direction in space is particularly preferred.

Very particular preference is given to the configuration of the second electrode (3) according to the first preferred embodiment as corrugated or zig-zagged in one direction in space, with the angle between the polymer membrane (2) and each deformation in the sense of the zig-zagged configuration being from 5° to 80°, preferably from 20° to 75°, particularly preferably from 30° to 70°.

This is particularly advantageous because it results in a comparatively larger number of lines of contact between the polymer membrane (2) and the second electrode (3) and at the same time defined channels through which the hydroxide ions formed can be discharged in a simple manner, should this be desired, are formed between the polymer membrane (2) and the second electrode (3).

Finally, in alternative embodiments of the apparatus of the invention, the first electrode (1) can also be configured in the way just disclosed in connection with the second electrode.

The present invention further provides a process for producing an apparatus for the electrolytic reduction of oxygen, in which a first electrically conductive material is fixed either at a spacing of up to 5 mm to a polymer membrane or joined to the latter and in which a second electrically conductive, porous material is joined at points and/or lines of contact to the polymer membrane, characterized in that the second electrically conductive, porous material is deformed in a corrugated or zig-zagged fashion in one or two directions in space before it is joined to the polymer membrane.

The first electrically conductive material is that which has been disclosed above as material of the first electrode (1) in connection with the apparatus of the invention.

The polymer membrane is that which has been disclosed above as polymer membrane (2) in connection with the apparatus of the invention.

The second electrically conductive, porous material is that which has been disclosed above as material of the second electrode (3) in connection with the apparatus of the invention.

Here, the abovementioned materials are advantageous since they all have a high specific conductivity and at the same time can readily be deformed so that the process of the invention can be carried out in a simple manner.

The corrugated or zig-zagged deformation in one or two directions in space can be carried out by means of generally known processes for the working of metals. Such processes are, for example, deep drawing, bending, stretching, (hot) pressing, etc., of metal materials.

In a preferred embodiment of the process of the invention, the second electrically conductive, porous material is subjected to coating before being brought into contact with the polymer membrane (2).

In the preferred embodiment, coating is effected firstly by treatment of the second electrically conductive, porous material with a mixture comprising at least a proportion of metal powder and a proportion of particles of a fluorinated polymer.

In further preferred embodiments of the process of the invention, the mixture is a suspension. The treatment can here be dipping into or spraying with the suspension.

The liquid in which the suspension of the abovementioned particles is present can be water or an organic solvent. If an organic solvent is used, this is an organic solvent which is not able to dissolve the fluorinated polymer.

However, preference is given to using water as liquid for producing the suspension.

The suspension can also comprise a thickener. Thickeners are materials which can dissolve in the liquid used for producing the suspension and significantly increase the dynamic viscosity of the liquid even in small amounts.

Nonexhaustive examples of such thickeners are derivatives of cellulose such as hydroxypropylcellulose, methylcellulose, ethylcellulose, etc.

Preference is given to using a thickener and this is particularly preferably methylcellulose.

The suspension can further comprise a detergent.

Detergents are, for example, ionic or nonionic surfactants, for instance the materials generally known under the trade name family Tween or the materials known under the trade name family Triton.

Preference is given to using a detergent and this is particularly preferably Triton-X 100.

The suspension which is used for coating the second electrically conductive, porous material usually comprises a proportion of from 10 to 70% by weight of the metal powder and a proportion of from 0.1 to 20% by weight of the particles of the fluorinated polymer.

In preferred embodiments of the process of the invention, the suspension contains from 30 to 80% by weight of water, from 10 to 70% by weight of the metal powder, from 0.1 to 20% by weight of the particles of the fluorinated polymer, from 0.05 to 1.5% by weight of the thickener and from 0.1 to 2% by weight of the detergent, where the proportions add up to 100% by weight.

After treatment of the second electrically conductive, porous material with one of the abovementioned suspensions, the material obtained is usually, in the preferred development, dried and subsequently sintered.

In a further preferred development, drying can also be carried out in the manner of hot pressing together with the deformation according to the process of the invention. Drying is usually carried out at temperatures of from 60° C. to 200° C. If drying is carried out according to the further preferred development as hot pressing with simultaneous deformation, drying is carried out under a pressure above ambient temperature (1013 hPa), with the pressure being applied by means of a mechanical apparatus comprising a negative mould for the deformation of the resulting second electrically conductive, porous material.

Drying is advantageous because it enables the residues of liquid of the suspension for coating the second electrically conductive, porous material to be removed, so that these residues cannot remain as film on the surface and thus increase the ohmic resistance.

Sintering is usually carried out at temperatures of from 200° C. to 400° C.

Sintering is advantageous because it enables the residues of any thickener and/or detergent still present on the surface of the second electrically conductive, porous material to be removed by converting such residues into, for example, gaseous compounds, e.g. carbon dioxide and water vapour. They can therefore not remain as film on the surface and thus increase the ohmic resistance, which would be disadvantageous.

At the same time, the fluorinated polymers usually do not have a significant vapour pressure at these temperatures or do not yet decompose to an appreciable extent at these temperatures so that they merely soften and together with the metal powder, which at the interfaces sinters with the second electrically conductive, porous material and with itself, form a conductive but chemically stabilizing film.

After coating in the form of a treatment with the suspension and subsequent drying and sintering, a coating which consists essentially of only the material of the metal powder and small amounts of fluorinated polymer is thus obtained on the second electrically conductive, porous material.

Such a layer is advantageous because it at the same time has a high conductivity and an advantageous chemical stability together with a desired hydrophilicity.

The joining of the first electrically conductive material to the polymer membrane and the coated or uncoated second electrically conductive, porous material can be effected by means of mechanical elements such as frames or clamping elements but also by joining in the form of (hot) pressing together according to the above-described further preferred development during coating.

The present invention further provides for the use of the apparatus of the invention or of the apparatuses obtained by the process of the invention in processes for the electrochemical reduction of oxygen and/or for the electrochemical oxidation of chloride to chlorine.

Finally, the present invention provides a process for chloralkli electrolysis, in which chlorine and sodium hydroxide are formed electrochemically in two reaction zones separated by a polymer membrane (2) surrounded by one of two electrodes (1 and 3), with a sodium chloride solution being present in the first reaction zone and a solution comprising molecularly dissolved oxygen being present in the other reaction zone, characterized in that the reaction zone in which the solution comprising molecularly dissolved oxygen is brought into contact with a gas- and liquid-permeable electrode (3) which is deformed in a corrugated and/or zig-zagged manner in one and/or two directions in space relative to the polymer membrane (2) with which it is in contact and in that the sodium chloride solution is brought into contact with a gas- and liquid-permeable electrode (1) and a potential of less than 2.3 V is applied between the two electrodes.

Preferred embodiments of the process of the invention in respect of the electrodes (1 and 3) used in the process or in respect of the polymer membrane (2) used in the process of the invention comprise the embodiments described in the context of the apparatus of the invention.

The process of the invention is usually operated by supplying a current density of from 2 to 10 kA/m² at the above-described potential.

In further preferred embodiments of the process of the invention, a potential of less than 2 V is applied at a current density of from 2 to 6 kA/m².

Such processes are particularly advantageous because the reduced potential at the above-mentioned current densities using a reduced power compared to the prior art allows reduction of oxygen and oxidation of chloride to chlorine at the same time.

The invention is illustrated below with the aid of figures and examples, but without being restrictive thereto.

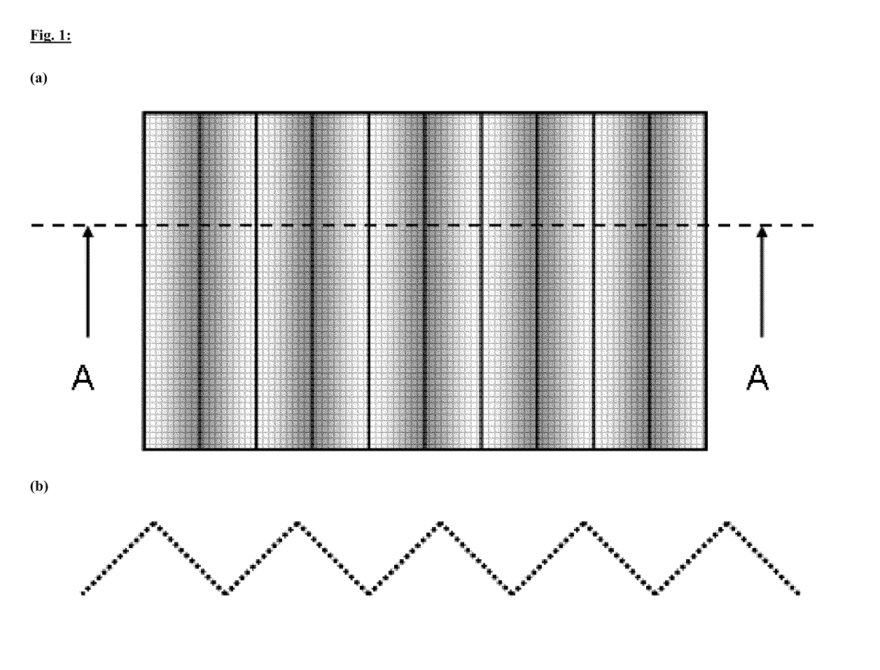

FIGS. 1 to 3 show preferred embodiments of an electrode of the apparatus of the invention using a grid.

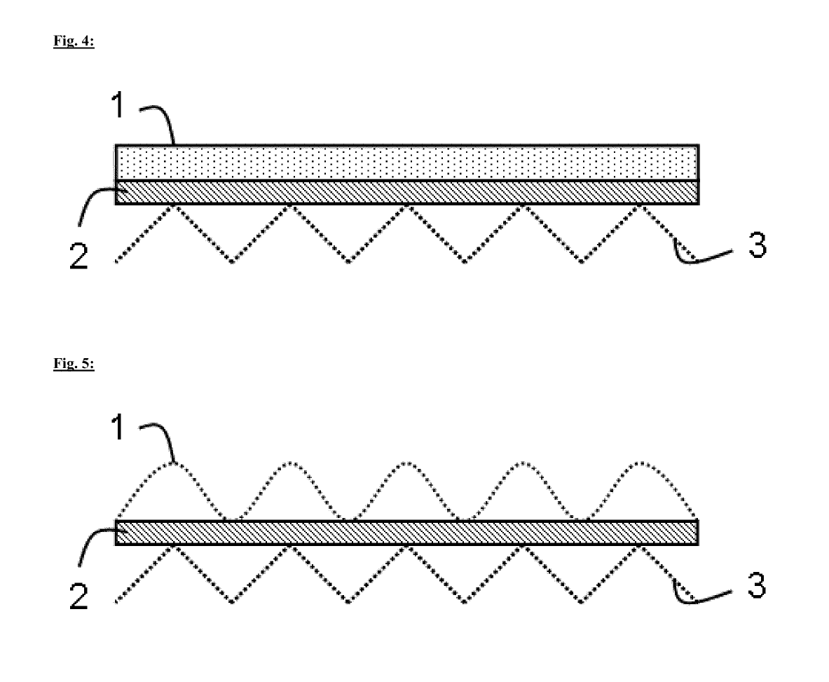

FIGS. 4 to 6 show preferred embodiments of the apparatus of the invention using the electrodes shown in FIGS. 1 to 3.

FIG. 7 shows a comparison of the plot of cell potential versus current density for a process according to the invention and a process which is not according to the invention.

FIG. 1 specifically shows a zig-zagged deformation in one direction in space of an electrode of the apparatus of the invention made of a grid material. FIG. 1 (a) depicts a plan view of an electrode area and FIG. 1 (b) depicts a sectional view along the line A-A of the same electrode shown in FIG. 1 (a).

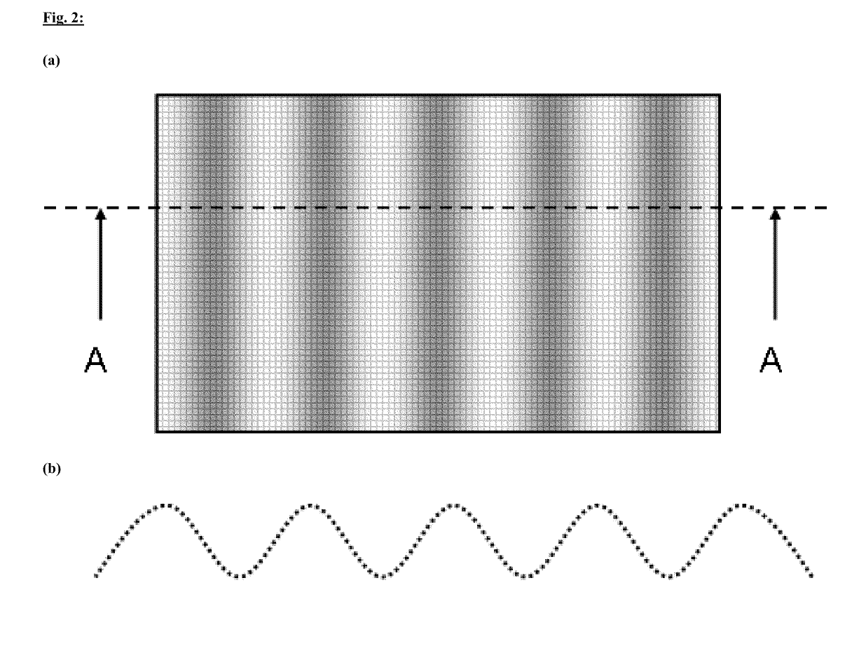

FIG. 2 specifically shows a corrugated deformation in one direction in space of an electrode of the apparatus of the invention made of a grid material. FIG. 2 (a) depicts a plan view of an electrode area and FIG. 2 (b) depicts a sectional view along the line A-A of the same electrode shown in FIG. 2 (a).

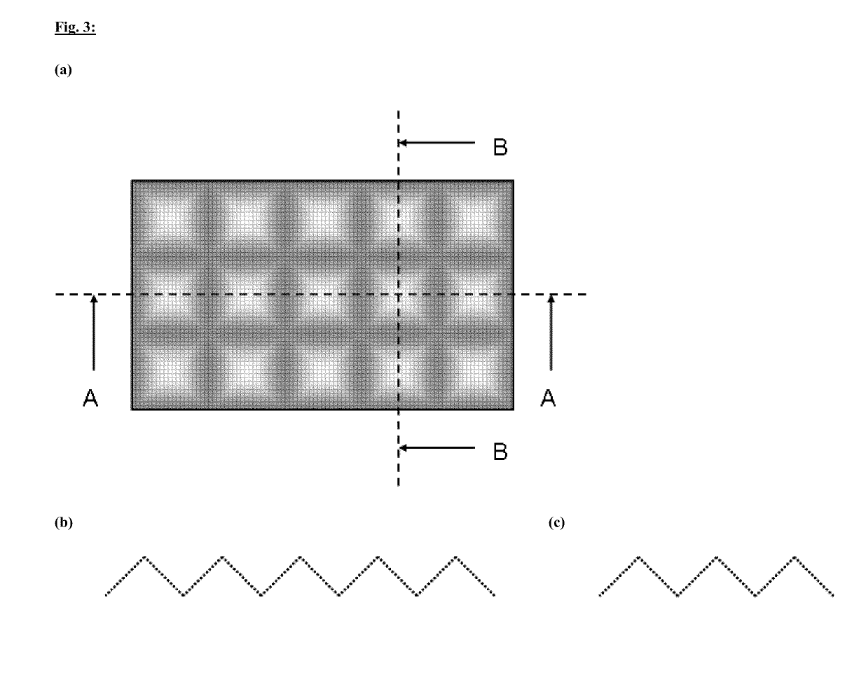

FIG. 3 specifically shows a zig-zagged deformation in two directions in space of an electrode of the apparatus of the invention made of a grid material. FIG. 3 (a) depicts a plan view of an electrode area and FIG. 3 (b) depicts a sectional view along the line A-A of the same electrode shown in FIG. 3 (a) while FIG. 3 (c) shows a sectional view along the line B-B.

FIG. 4 specifically shows a side view of a first embodiment of the apparatus of the invention containing a first electrode (1) in the form of a woven fabric which is flat and in contact over the entire surface of one side with a polymer membrane (2) and a second electrode (3) of the embodiment depicted in FIG. 1 which is in contact with the polymer membrane (2) at lines of contact.

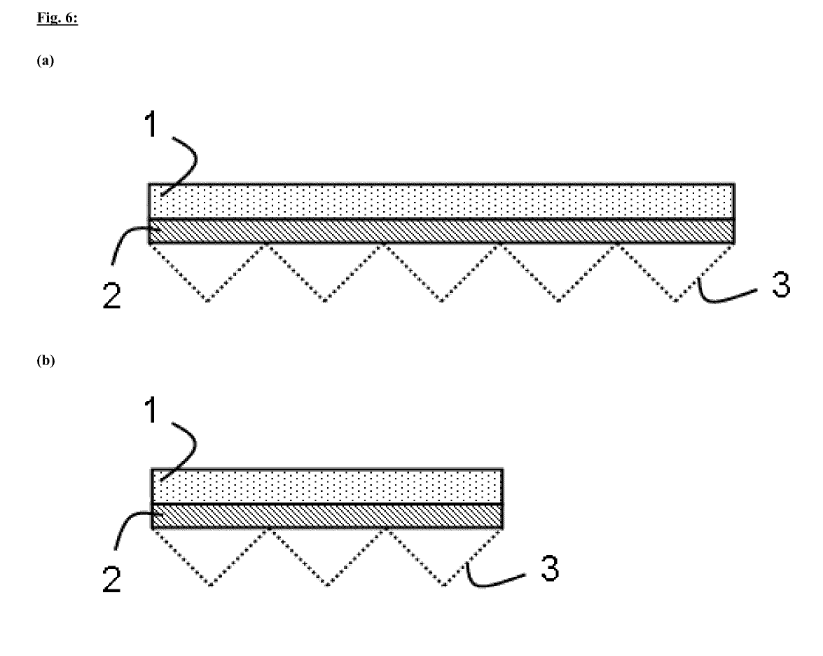

FIG. 5 specifically shows a side view of a second embodiment of the apparatus of the invention containing a first electrode (1) in the form of a mesh of the embodiment depicted in FIG. 2 which is in contact with the polymer membrane (2) at lines of contact and a second electrode (3) of the embodiment depicted in FIG. 1 which is likewise in contact with the polymer membrane (2) at lines of contact.

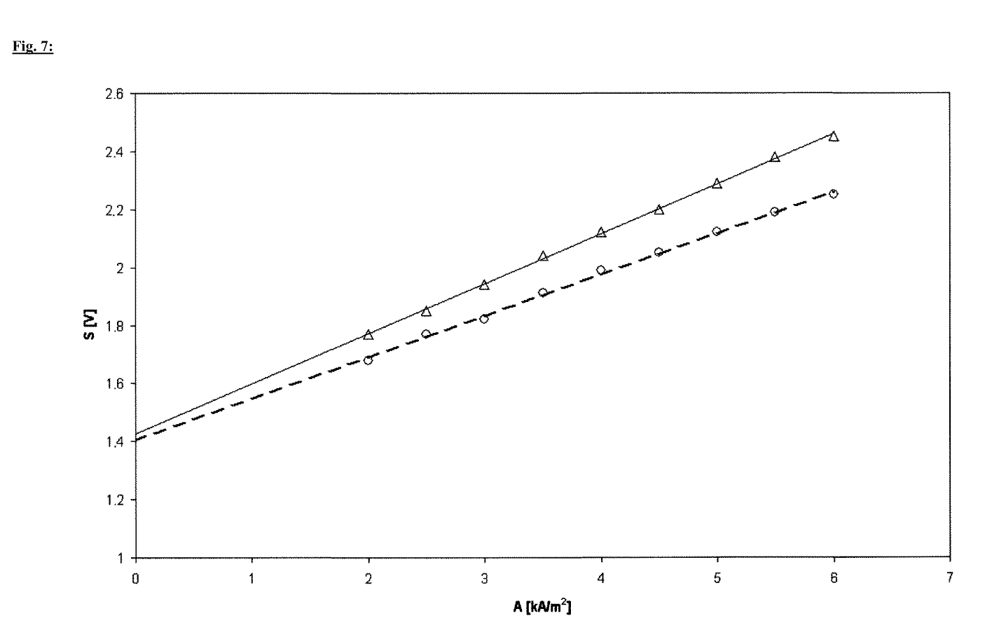

FIG. 6 specifically shows, in (a) and (b), the two side views of a third embodiment of the apparatus of the invention containing a first electrode (1) in the form of a woven fabric which is flat and is in contact over the entire area of one side with a polymer membrane (2) and a second electrode (3) of the embodiment depicted in FIG. 3 which is in contact with the polymer membrane (2) at points of contact.

FIG. 7 shows the plot of cell potential (S) in volts as a function of the current density (A) in kA/m² for chloralkali electrolysis by the process of the invention, in particular according to the data from Example 7 (dots and thick broken line) and for chloralkli electrolysis by a process which is not according to the invention, in particular according to the data from Comparative Example 7 (triangles and thin continuous line).

### EXAMPLES

### Examples 1-3

### Production of Electrodes According to the Invention

Flat nickel meshes (from Haver and Boecker) having a mesh opening of 0.5 mm and a wire thickness of 0.1 mm were coated with various suspensions having compositions as shown in Table 1 by firstly spraying the meshes with the suspensions 1 to 3, then shaping by bending at 130° C. at in each case 60° angles with distances of 3 mm to a planar surface and then sintering at 340° C.

TABLE 1
Compositions of the suspensions for coating the two electrodes

| Material, Use | Suspension 1 | Suspension 2 | Suspension 3 |
|---|---|---|---|
| (Source) | (Example 1) | (Example 2) | (Example 3) |
| Silver power (SF9ED, | 30% by | 30% by | 30% by |
| from Ferro GmbH) | weight | weight | weight |
| Methylcellulose as | 0.5% by | 0.5% by | 0.5% by |
| thickener (Walcocel | weight | weight | weight |
| MKX 70.000 PP 01, | | | |
| from Wolff Cellulosics | | | |
| GmbH & Co KG) | | | |
| Triton X-100 as | 0.5% by | 0.5% by | 0.5% by |
| detergent (from Fluka | weight | weight | weight |
| Chemie AG) | | | |
| Polytetrafluoroethylene | 0.3% by | 0.61% by | 0.93% by |
| (PTFE 5035R, from | weight | weight | weight |
| Dyneon) | | | |
| Water | 68.7% by | 68.39% by | 68.07% by |
| | weight | weight | weight |

Three electrodes according to the invention are obtained.

### Comparative Examples 1-3

### Production of Electrodes which are not According to the Invention

Three electrodes were produced in a manner analogous to Examples 1-3 with the sole difference that they were not shaped but remained in flat form.

### Examples 4-6

### Production of Apparatuses According to the Invention Having Electrodes According to Examples 1-3

The electrodes from Examples 1-3 were brought into contact as cathodes with a standard electrode (from DeNora Deutschland GmbH) of titanium as anode and a polymer membrane of Nafion 982WX (from DuPont) by means of clamping frames to give an electrolysis cell and the electrodes were electrically connected to one another via a source of electric potential and current. The free projection area, which in the case of the flat anode was equal to the active area of the electrode, was fixed at 25 cm² by means of the frame. The active surface area of the electrodes from Examples 1-3 was 48 cm² in each case as a result of the deformation.

### Comparative Examples 4-6

### Production of Apparatuses According to the Invention Having Electrodes According to Comparative Examples 1-3

Electrolysis cells were produced as per each of Examples 4-6 with the sole difference that an electrode from Comparative Examples 1-3 was used in each case instead of the electrode from Examples 1-3 and that a gap of 3 mm was provided between the electrodes of Comparative Examples 1-3 and the polymer membrane. These were flat and accordingly had an active surface area of 25 cm² in each case.

### Example 7

### Chloralkali Electrolysis Process Using the Apparatus According to Example 4

The electrolysis cell according to Example 4 (electrode from Example 1) was placed in a vessel so that two reaction zones separated by the electrolysis cell were formed. A 30% strength by weight, aqueous sodium hydroxide solution was introduced on the side of the electrode from Example 1 while a 20% strength by weight aqueous sodium chloride solution was introduced on the side of the standard electrode. Both solutions were recirculated through the respective reaction zones via a large reservoir in order to achieve an approximately constant concentration of the constituents over a period of operation of 100 hours.

The gauge pressure on the side of the sodium hydroxide solution was about 180 mbar, with the gauge pressure of the oxygen introduced into the sodium hydroxide solution making up 30 mbar of the gauge pressure and the remaining gauge pressure of 150 mbar resulting from the elevated reservoir for the sodium hydroxide. The process was carried out at a temperature of 90° C.

Measurements were carried out over a period of 100 hours at various, applied cell potentials and current densities. The results are independent of time within the 100 hours and are shown in FIG. 7 as cell potential plotted against current density.

### Comparative Example 7

### Chloralkali Electrolysis Process Using the Apparatus According to Comparative Example 4

An experiment equivalent to each of the experiments in Example 7 was carried out with the sole difference that the electrolysis cell from Comparative Example 4 (electrode from Comparative Example 1) was now used.

The results are likewise independent of time and are shown in FIG. 7 as cell potential plotted against current density.

Comparison of Example 7 with Comparative Example 7 shows that, at the same current densities, the apparatus according to the invention requires a cell potential which at 4 kA/m² is significantly lower by 130 mV compared to the apparatus which is not according to the invention. To rule out the possibility that the advantageous effect of the reduced cell potential is due to an unfortunately chosen gap between the second electrode which is not according to the invention and the polymer membrane, the gap was halved to just 1.5 mm. However, a reduction in the cell potential by about 60 mV at 4 kA/m² was measured. This rules out the possibility that the advantageous effect of the apparatus according to the invention was attributable only to an average reduction in the gap width between second electrode and polymer membrane.

1. Apparatus for the electrolytic reduction of oxygen containing a first electrode (1) as anode, a polymer membrane (2) and a second gas- and liquid-permeable electrode (3) as cathode, wherein the second electrode (3) is in contact with the polymer membrane (2) at points and/or lines of contact.

2. Apparatus according to claim 1, wherein the first electrode (1) is in the form of a plate, a flat mesh, a flat grid or a flat woven fabric.

3. Apparatus according to claim 1, wherein the second electrode (3) is corrugated or zig-zagged in one direction in space.

4. Apparatus according to claim 3, wherein the second electrode (3) is zig-zagged and the angle between polymer membrane (2) and the zig-zagged electrode is from 5° to 80°.

5. Process for producing an apparatus for the electrolytic reduction of oxygen, in which a first electrically conductive material is fixed either at a spacing of up to 5 mm to a polymer membrane or joined to the latter and in which a second electrically conductive, porous material is joined at points and/or lines of contact to the polymer membrane, wherein the second electrically conductive, porous material is deformed in a corrugated or zig-zagged fashion in one or two directions in space before it is joined to the polymer membrane.

6. Process according to claim 5, wherein the second electrically conductive, porous material is subjected to coating by treatment of the second electrically conductive, porous material with a mixture comprising at least a proportion of metal powder and a proportion of particles of a fluorinated polymer before being brought into contact with the polymer membrane (2).

7. Process according to claim 6, wherein the mixture is a suspension.

8. Process according to claim 7, wherein after treatment of the second electrically conductive, porous material with said suspension, the material obtained is dried and subsequently sintered, with drying being carried out as hot pressing together with the deformation.

9. Process for the electrochemical reduction of oxygen and/or the electrochemical oxidation of chloride to chlorine, wherein said process is carried out in the apparatus of claim 1.

10. Process for chloralkli electrolysis, in which chlorine and sodium hydroxide are formed electrochemically in two reaction zones separated by a polymer membrane (2) surrounded by one of two electrodes (1 and 3), with a sodium chloride solution being present in the first reaction zone and a solution comprising molecularly dissolved oxygen being present in the second reaction zone, wherein the reaction zone in which the solution comprising molecularly dissolved oxygen is brought into contact with a gas- and liquid-permeable electrode (3) which is deformed in a corrugated and/or zig-zagged manner in one and/or two directions in space relative to the polymer membrane (2) with which it is in contact and the sodium chloride solution is brought into contact with a gas- and liquid-permeable electrode (1) and a potential of less than 2.3 V is applied between the two electrodes.

11. Apparatus of claim 4, wherein said angle is from 20° to 75°.

12. Apparatus of claim 11, wherein said angle is from 30° to 70°.
